(19) United States
(12) Patent Application Publication
(10) Pub. No.: US 2020/0067281 A1
(43) Pub. Date: Feb. 27, 2020

(54) INHOMOGENEOUS FOCUSING AND BROADBAND METASURFACE QUANTUM-CASCADE LASERS

(71) Applicants: Christopher CURWEN, Los Angeles, CA (US); THE REGENTS OF THE UNIVERSITY OF CALIFORNIA, Oakland, CA (US)

(72) Inventors: Christopher CURWEN, Los Angeles, CA (US); Benjamin Stanford WILLIAMS, Los Angeles, CA (US); Luyao XU, Los Angeles, CA (US)

(21) Appl. No.: 16/339,687

(22) PCT Filed: Oct. 5, 2017
(86) PCT No.: PCT/US2017/055370

§ 371 Date: Apr. 4, 2019

Related U.S. Application Data
(60) Provisional application No. 62/405,001, filed on Oct. 6, 2016.

(51) Int. Cl. H01S 5/34; H01S 5/42; H01S 5/14

(52) U.S. Cl. CPC H01S 5/3401; H01S 2302/02; H01S 5/141; H01S 5/423

(57) ABSTRACT

A reflectarray metasurface for quantum-cascade lasing includes: (1) a substrate; and (2) an array of subcavities disposed on the substrate. Each subcavity in the array of subcavities includes (a) a first metallic layer disposed on the substrate; (b) a layer of a quantum-cascade laser active material disposed on the first metallic layer; and (c) a second metallic layer disposed on the layer of the quantum-cascade laser active material. At least some subcavities in the array of subcavities have inhomogeneous widths, and the array of subcavities is configured to reflect an incident light of at least one resonant frequency with amplification.

### CROSS-REFERENCE TO RELATED APPLICATION

This application claims the benefit of U.S. Provisional Application No. 62/405,001, filed Oct. 6, 2016, the content of which is incorporated herein by reference in its entirety.

### STATEMENT REGARDING FEDERALLY SPONSORED RESEARCH OR DEVELOPMENT

This invention was made with Government support under NNX16AC73G, awarded by the Nat'l Aeronautics & Space Administration, and under Grant Number 1407711, awarded by the National Science Foundation. The Government has certain rights in the invention.

### TECHNICAL FIELD

This disclosure relates to quantum-cascade lasers including inhomogeneous active metasurfaces.

### BACKGROUND

The ability to engineer the phase of scattered light from planar surfaces is a powerful tool for beam engineering, which allows the replacement of bulky optical components with corresponding thin and flat structures of lighter weight and smaller size.

It is against this background that a need arose to develop the embodiments described herein.

### SUMMARY

Some embodiments are directed to a reflectarray metasurface for quantum-cascade lasing. In some embodiments, the metasurface includes: (1) a substrate; and (2) an array of subcavities disposed on the substrate. Each subcavity in the array of subcavities includes (a) a first metallic layer disposed on the substrate; (b) a layer of a quantum-cascade laser active material disposed on the first metallic layer; and (c) a second metallic layer disposed on the layer of the quantum-cascade laser active material. At least some subcavities in the array of subcavities have inhomogeneous widths, and the array of subcavities is configured to reflect an incident light of at least one resonant frequency with amplification.

In some embodiments of the metasurface, a width of at least one, or each, subcavity at a particular position in the array of subcavities is determined, or varies, according to a distance from a reference point (e.g., a center) of the metasurface to the particular position.

In some embodiments of the metasurface, widths of subcavities at respective positions in the array of subcavities are determined, or vary, according to distances from a reference point (e.g., a center) of the metasurface to the respective positions.

In some embodiments of the metasurface, a width of at least one, or each, subcavity varies along its lengthwise direction at least within a center biased region of the metasurface. For example, the width can vary between a maximum width and a minimum width, where the maximum width is at least about 1.05 times greater than the minimum width, such as at least about 1.1 times greater, at least about 1.2 times greater, at least about 1.3 times greater, at least about 1.4 times greater, or at least about 1.5 times greater. In some embodiments, a width of at least one, or each, subcavity at respective positions along its lengthwise direction is determined, or varies, according to distances from a reference point (e.g., a center) of the metasurface to the respective positions.

In some embodiments of the metasurface, a width at a particular position of a particular subcavity is determined, or varies, according to a distance from a reference point (e.g., a center) of the metasurface to the particular position of the particular subcavity.

In some embodiments of the metasurface, widths of subcavities in the array of subcavities are spatially modulated so that a reflected light from the metasurface has a phase shift that varies according to a distance from a reference point (e.g., a center) of the metasurface. In some embodiments, the widths are spatially modulated so that a reflected light from the metasurface has a phase shift that increases according to a distance from a reference point (e.g., a center) of the metasurface. In some embodiments, the widths are spatially modulated so that a reflected light from the metasurface has a parabolic phase front.

In some embodiments of the metasurface, the array of subcavities includes a repeating unit cell of a group of multiple subcavities having different widths. In some embodiments, a first subcavity per unit cell has a first width, and a second subcavity per unit cell has a second width different from the first width. For example, the first width is greater than the second width, such as at least about 1.05 times greater, at least about 1.1 times greater, at least about 1.2 times greater, at least about 1.3 times greater, at least about 1.4 times greater, or at least about 1.5 times greater.

In some embodiments of the metasurface, a dielectric layer is disposed between the second metallic layer and the layer of quantum-cascade laser active material for a portion of each subcavity outside of a reference center region of the metasurface, but is not disposed between the second metallic layer and the layer of quantum-cascade laser active material for another portion of the subcavity inside the center region.

In some embodiments of the metasurface, a period of the array of subcavities is less than a wavelength of the incident light of the resonant frequency.

In some embodiments of the metasurface, each subcavity tapers at edges of the metasurface and terminates at an unbiased region of the metasurface.

In some embodiments of the metasurface, the metasurface provides a gain peak in a range of about 1 Terahertz (THz) to about 10 THz, and where a reflectance of the metasurface is more than unity (1) at the gain peak.

In some embodiments of the metasurface, the array of subcavities is configured to reflect and focus the incident light of the resonant frequency with amplification.

In some embodiments of the metasurface, the first metallic layer includes copper, gold, or another metal, or an alloy or other combination of two or more metals. In some embodiments, the quantum-cascade laser active material includes a GaAs/AlGaAs material system, InGaAs/InAlAs material system, or other combination of two or more semiconductor materials. In some embodiments, the second metallic layer includes titanium, tantalum, gold, or a combination thereof, or another metal, or other alloy or combination of two or more metals. In some embodiments, the substrate is a GaAs substrate or other semiconductor substrate.

Additional embodiments are directed to a reflectarray metasurface for quantum-cascade lasing. In some embodiments, the metasurface includes: (1) a substrate; (2) a first metallic layer disposed on the substrate; (3) an array of quantum-cascade laser active strips and spaced with a period, the array of quantum-cascade laser active strips being disposed on the first metallic layer such that a portion of the first metallic layer is covered by the array of quantum-cascade laser active strips and another portion of the first metallic layer is exposed from the array of quantum-cascade laser active strips; and (4) an array of metallic strips disposed on the array of quantum-cascade laser active strips. At least some strips in the array of quantum-cascade laser active strips have inhomogeneous widths, and the metasurface is configured to reflect an incident light of at least one resonant frequency with amplification.

In some embodiments of the metasurface, widths of strips in the array of quantum-cascade laser active strips are spatially modulated so that a reflected light from the metasurface has a phase shift that varies according to a distance from a reference point of the metasurface.

In some embodiments of the metasurface, widths of strips in the array of quantum-cascade laser active strips are spatially modulated so that a reflected light from the metasurface has a phase shift that increases according to a distance from a reference point of the metasurface.

In some embodiments of the metasurface, the array of quantum-cascade laser active strips includes a repeating unit cell of a group of multiple strips having different widths.

Additional embodiments are directed to a quantum-cascade laser. In some embodiments, the quantum-cascade laser includes: (1) a reflectarray metasurface according to any of the foregoing embodiments; and (2) an output coupler connected to the metasurface and which forms a cavity with the metasurface to generate a quantum-cascade laser beam.

In some embodiments of the quantum-cascade laser, the output coupler is a flat reflector, and the quantum-cascade laser beam is reflected between the flat reflector and the metasurface before emitting.

In some embodiments of the quantum-cascade laser, the quantum-cascade laser further includes a heat sink connected to the metasurface, and a cryostat that houses the heat sink and the metasurface, where the cryostat includes a window for transmission of the quantum-cascade laser beam. In some embodiments, the output coupler is disposed or housed within the cryostat. In some embodiments, the output coupler is disposed externally to the cryostat.

In some embodiments of the quantum-cascade laser, the quantum-cascade laser further includes an actuator connected between the metasurface and the output coupler to adjust a spacing therebetween to control a cavity length.

In some embodiments of the quantum-cascade laser, the quantum-cascade laser further includes an electrical source connected to the metasurface to selectively apply an electrical bias to a reference center region of the metasurface, but without applying an electrical bias to a remaining peripheral region of the metasurface outside of the center region.

Other aspects and embodiments of this disclosure are also contemplated. The foregoing summary and the following detailed description are not meant to restrict this disclosure to any particular embodiment but are merely meant to describe some embodiments of this disclosure.

### BRIEF DESCRIPTION OF THE DRAWINGS

For a better understanding of the nature and objects of some embodiments of this disclosure, reference should be made to the following detailed description taken in conjunction with the accompanying drawings.

FIG. 1. (a) SEM image of an about 2×2 mm² active focusing metasurface with wire bonds. Portions of ridges within the dashed circle (about 1 mm diameter) are electrically biased via an electrical source connected to the focusing metasurface via the wire bonds; an area outside includes a SiO₂ insulation layer between a top metallic contact and a QC material. (b) Schematic for a THz QC-VECSEL based on the active focusing metasurface acting as an amplifying concave mirror. (c) Zoom-in SEM image of a part of the focusing metasurface showing ridge width variation along and across ridges. (d) Schematic cross-sectional diagram of the focusing metasurface.

FIG. 2. (a) Simulated reflectance (top) and reflection phase shift (bottom) versus ridge width for a metal-metal waveguide array with period of about 70 μm, with about 30 cm⁻¹ bulk gain assumed in a QC gain medium. Inset is an electric field amplitude profile of the excited TM₀₁ mode in the reflection simulation. (b) Designed ridge width distribution for a focusing metasurface of R=about 10 mm at about 3.4 THz (top), and simulated phase front of reflected wave with a plane wave incident thereon, in comparison with a target parabolic phase front (bottom).

FIG. 3. (a) Experimental configuration of a focusing metasurface QC-VECSEL. The tilt angle δ_{x/y} indicates the degree of output coupler tilting around y/x axis from a perfectly aligned position, as the arrows show. (b) Pulsed P-I-V curves at about 77 K for different δ_{y} (with δₓ=0) for R=about 10 mm focusing metasurface (M3.4). (c) The measured threshold current density change ratio with respect to Jₜₕ at perfect alignment with δₓ and δ_{y} for QC-VECSELs based upon three different metasurfaces: R=about 10 mm and about 20 mm with about 1 mm diameter circular bias area, and a uniform metasurface with about 1.5 mm diameter circular bias area. The solid lines in the top part are the calculated threshold bulk gain gₜₕ change with the tilt angle δ_{y}.

FIG. 4. (a) Pulsed P-I-V curves for R=about 10 mm focusing metasurface QC-VECSEL designed for about 3.4 THz, paired with output coupler 1 (OC1) and output coupler 2 (OC2) respectively at about 77 K. (b) Pulsed and continuous wave (cw) P-I-V curves for the QC-VECSEL composed of the R=about 10 mm focusing metasurface and OC2 at about 6 K. (c) Lasing spectra measured using a Nicolet FTIR using about 0.25 cm⁻¹ resolution for QC-VECSELs based on four focusing metasurfaces M3.2, M3.3, M3.4, and M3.5 paired with either OC1 or OC2 at about 77 K.

FIG. 5. (a) The measured beam pattern from a focusing metasurface QC-VECSEL with R=about 10 mm. (b) The measured beam pattern from a focusing metasurface QC-VECSEL with R=about 20 mm. The angular resolution in measurement is about 0.5°. Black dashed lines are Gaussian curve fits to the one-dimensional (1D) beam cuts through the beam center. 1D beam cuts are also plotted in dB scale. Beams are measured at about 77 K.

FIG. 6. M² factor measurement results for an output beam directly from a focusing metasurface QC-VECSEL with R=about 20 mm. The beam radius is measured along the optical axis (z axis) in both x and y direction after being focused by a polymethylpentene (TPX) lens of about 50-mm focal length which is placed about 17 cm away from the VECSEL, and is represented by circles in (a) and (b), with the curve fitting results plotted in dashed line. The inset shows the knife-edge measurement raw data at beam waist position with curve fitting shown in dashed curve.

FIG. 7. (a) Reflectivity magnitude and phase distributions for four calculation cases. (b) Calculated far-field beam patterns, cavity mode intensity profiles on metasurface and output coupler for the four cases.

FIG. 8. (a) Schematic of an intra-cryostat cavity design. (b) Schematic of the intra-cryostat QC-VECSEL mounted inside a cryostat. (c) Front and side views of the actual intra-cryostat cavity setup.

FIG. 9. (a) cw and pulsed P-I-V curves at about 6 K and about 77 K for an intra-cryostat QC-VECSEL. (b) Lasing spectra at about 82 K for the cw mode and about 77 K for the pulsed mode at different current injection levels.

FIG. 10. (a) Beam pattern measured at about 77 K in the pulsed mode. (b) 1D beam profiles measured at above about 77 K in the cw mode at two biases, compared with the pulsed mode profiles. Dark dashed lines are the fitted Gaussian curves.

FIG. 11. Pulsed P-I curves measured at different cryostat temperatures. The inset shows the plot of the measured threshold current density Jₜₕ versus cryostat temperature, and the curve fits in the dark dashed line.

FIG. 12. (a) Reflectance spectrum (lower) and simulated vertical electric field (upper) of a homogeneous single resonator metasurface, with a FWHM gain of about 230 GHz. (b) Reflectance spectrum (lower) and simulated vertical electric field (upper) of a coupled-double-resonator metasurface with a FWHM gain of about 1400 GHz.

FIG. 13. Experimentally measured set of laser emission spectra from a coupler-resonator metasurface VECSEL as a cavity length is changed using a piezoelectric actuator. The spectra show that the metasurface exhibits a gain bandwidth of about 1.08 THz, and a single mode is tunable over about 670 GHz.

FIG. 14. Schematic cross-sectional diagram of a QC-VECSEL for broadband operation.

### DETAILED DESCRIPTION

### Focusing Metasurface Quantum-Cascade Laser

The ability to engineer the phase of scattered light from planar surfaces is a powerful tool for beam engineering, which allows the replacement of bulky optical components with corresponding thin and flat structures of lighter weight and smaller size. For example, in the microwave regime, space-fed parabolic reflectors can be replaced with reflectarray antennas, which comprise arrays of resonant patch antennas structured to engineer a spatially dependent reflection phase by varying a characteristic dimension of the patch antennas. This type of reflectarray lenses are also used in the millimeter (mm)-wave, terahertz (THz), and mid-infrared (mid-IR) ranges. Across the infrared (IR) and visible spectrum, metallic antennas, plasmonic antennas, and dielectric antennas are used to form a variety of reflectarray and transmitarray metasurface for optical components, including lenses for focusing and imaging. However, less effort has been devoted to integrating a gain into a metasurface, either for mitigating losses, or for implementing laser devices. Reasons might be that, in the IR and visible spectrum, the metallic or plasmonic components that form metasurfaces are prohibitively lossy. In the THz frequency range, however, metals have modest losses.

Some embodiments of this disclosure are directed to a THz vertical-external-cavity surface-emitting-laser (VECSEL) that includes an active focusing reflectarray metasurface based on quantum-cascade (QC) gain material, which differs from a QC VECSEL that includes an active non-focusing reflectarray metasurface.

For a non-focusing reflectarray metasurface based on a QC gain material (or a QC laser active material), the reflectarray metasurface is formed of a periodic array of substantially identical low-Q subcavities. Each subcavity is a metal-metal waveguide of width w loaded with an electrically biased QC active material, which can reflect and amplify incident THz radiation. The active metasurface can be paired with a flat output coupler (or flat reflector) to form a plano-plano Fabry-Perot (FP) VECSEL cavity. In contrast to other on-chip cavity engineering approaches for THz QC-lasers, an output beam pattern of a QC-VECSEL is determined by the VECSEL cavity rather than the subcavities. Furthermore, with a proper choice of a reflectivity of the output coupler, an output power of the QC-VECSEL can be enhanced. As such, the QC-VECSEL disentangles the issue of beam engineering from output power optimization. Compared to a concave mirror output coupler, planar output couplers can be manufactured using lithographic techniques.

In some embodiments of this disclosure, a uniform metasurface formed of substantially identical subcavities are replaced with an inhomogeneous reflectarray metasurface formed of non-identical subcavities. The focusing reflectarray metasurface can act as an amplifying concave mirror (e.g., a parabolic concave mirror) to form a stable hemispherical cavity with a flat output coupler. In particular, the active focusing reflectarray metasurface is formed of spatially inhomogeneous reflectarray antenna elements that are loaded with QC laser active materials. The metasurface can impose a phase shift on a reflected beam, which increases substantially quadratically with a distance from a metasurface center. When electrically biased, the reflectarray metasurface can amplify and focus the reflected beam.

A reflectarray metasurface and a flat output coupler, when used together, form a QC-VECSEL with a hemispherical cavity. Due to the focusing effect, a significant improvement in cavity stability and output beam pattern is observed on the QC-VECSEL, compared to a non-focusing metasurface configuration. Specifically, the demonstrated lasers generated a directive and circular near-diffraction limited Gaussian beam with M² beam parameter as low as about 1.3 (or less) and brightness of about 1.86×10⁶ Wsr⁻¹m² (or more), which exhibited high slope efficiency for THz QC lasers and improved geometric stability compared to the plano-plano cavity. As such, high-power and high-brightness THz QC-VECSELs with excellent beam patterns can be achieved using the inhomogeneous reflectarray metasurface, which can find various applications in THz heterodyne detection in astrophysics and space science, biological and medical imaging/spectroscopy, non-destructive sensing, and so on. More generally, the inhomogeneous metasurface for phase and gain engineering within a laser cavity can be exploited for a wide variety of beam and wave front generation applications.

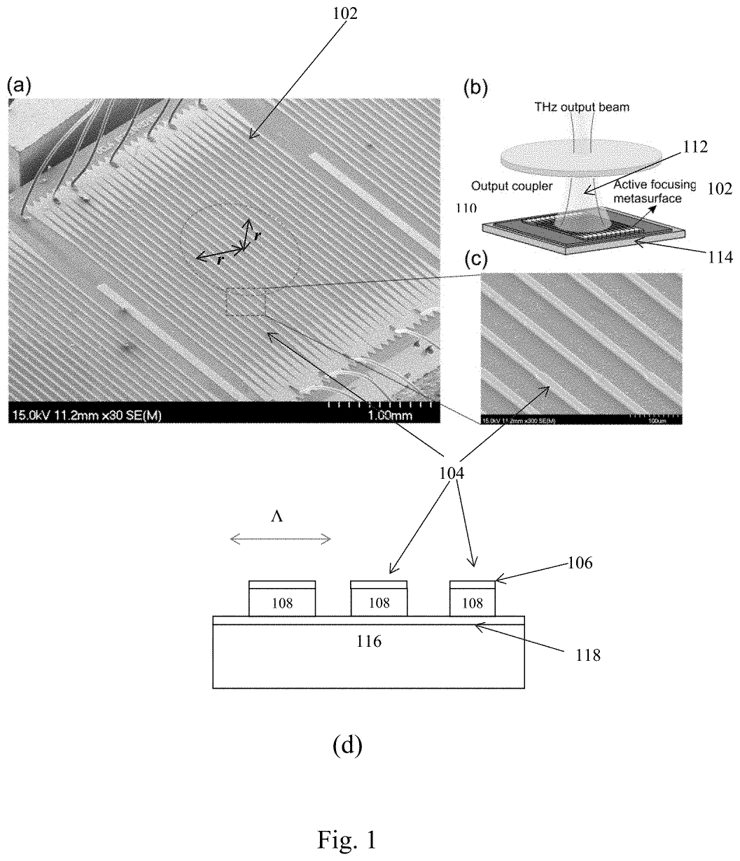

A QC-VECSEL with an active focusing reflectarray metasurface 102 is shown in FIG. 1 according to some embodiments. By way of example, the QC-VECSEL as shown operates in the THz range, for example, in the range of about 1 THz to about 5 THz. It shall be understood that, although embodiments can have many utilities in the THz frequency range, the QC-VECSEL can be applied in other frequency ranges as well by using appropriate active metasurfaces, for example, in the mid-IR and near-IR frequency ranges. FIG. 1(a) is a scanning electron microscope (SEM) image of the about 2×2 mm² active focusing metasurface 102 with wire bonds. Portions of subcavities (e.g., ridges) 104 within the dashed circle (about 1 mm diameter) are electrically biased. An area outside of the dashed circle has a SiO₂ insulation layer disposed between a top metallic layer 106 (e.g., a top metallic contact) and a QC active material 108 and is thus not electrically biased. FIG. 1(b) is a schematic diagram of the THz QC-VECSEL formed of the active focusing metasurface 102 in conjunction with a flat output coupler 110, in which the focusing metasurface 102 acts as an amplifying concave mirror. The focusing metasurface 102 and the output coupler 110 collectively form a cavity 112 (e.g., an external cavity). The focusing metasurface 102 can be mounted on a heat sink 114. FIG. 1(c) is a zoom-in SEM image of a part of the focusing metasurface 102 showing width variation along each individual subcavity 104 and across different subcavities 104. FIG. 1(d) is a schematic diagram of the focusing metasurface 102.

The focusing metasurface 102 includes a substrate 116 and an array of subcavities 104 disposed thereon in the form of inhomogeneous metal-metal waveguide ridges, as shown in FIGS. 1(a), (c), and (d). Each subcavity 104 includes the QC active material 108 sandwiched between a top metallic layer 106 and a bottom metallic layer 118. In the illustrated embodiments, the bottom metallic layers 118 are interconnected and integrally formed as a common metallic ground plane. Each subcavity 104 is structured to operate around its TM₀₁ mode cutoff resonant frequency, like an elongated patch antenna. Normally incident radiation is coupled to the QC active material 108, where it is amplified and re-radiated back to free space. Despite a weak dependence on the period Λ of the array, the resonance condition is approximately determined by w≈λ₀/2n, where w is a width of a waveguide ridge, λ₀ is the wavelength in free space, and n is the index of refraction in the QC active material 108. The electric field polarization of TM₀₁ mode is along the normal-to-ground direction, which satisfies the “polarization selection rule” for intersubband transitions. Each subcavity 104 is tapered to passive and lossy wire bonding areas on both ends, which helps to suppress lasing of the fundamental waveguide mode.

The about 2×2 mm² focusing metasurface 102 shown in FIG. 1(a) is formed of 29 tapered metal-metal waveguide ridges spaced with a period of Λ=about 70 which is chosen to be smaller than the free-space wavelength λ₀ in order to suppress Bragg scattering. The ridge width w at the metasurface center (center of the dashed circle) is chosen so that the resonant frequency of the subcavity 104 matches the intersubband gain spectrum peak. The focusing effect is achieved by spatially modulating the ridge width both along an individual ridge and transverse to the ridges, as shown in FIG. 1(c).

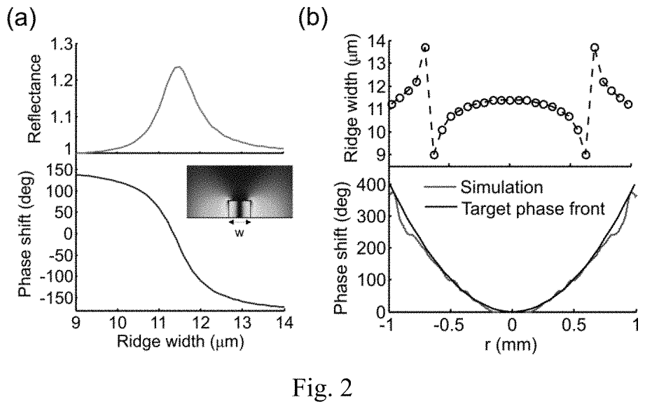

Depending on the resonance characteristics of metal-metal waveguides, at a particular frequency, nearly 2π change in a reflection phase can be obtained by altering the ridge width w around the resonance condition. FIG. 2(a) is a graph of simulated reflectance (top) and reflection phase shift (bottom) versus ridge width for a metal-metal waveguide array with a period of about 70 μm. In the calculation, a bulk gain of about 30 cm⁻¹ is assumed for the QC gain medium. FIG. 2(a) shows that a phase change of about 311° is achieved by varying w from about 9 μm to about 14 μm.

In some embodiments, the modulation of the ridge width is designed to achieve a target parabolic phase profile (for paraxial focusing) of 2πr²/Rλ₀, where r is the radial distance to the metasurface center and R is the effective radius of curvature (e.g., twice a desired focal length). The top part of FIG. 2(b) shows an example design of ridge width distribution for a focusing metasurface of R=about 10 mm at about 3.4 THz. The bottom part of FIG. 2(b) shows a simulated phase front of a reflected wave (with a plane wave incident on the metasurface), in comparison with a target parabolic phase front. As shown in FIG. 2(b), the numerically simulated profile matches well with the target parabolic profile, thus the focusing effect of the metasurface is verified. That the reflectance is highest near the resonance frequency provides an approximate “self-selection” of the correct frequency to obtain the desired phase profile. Four focusing metasurfaces with R=about 10 mm or about 20 mm were designed for four different frequencies in the range of about 3.2 THz to about 3.5 THz to overlap with the QC material bulk gain peak, which are labeled M3.2, M3.3, M3.4, M3.5 for the experiments illustrated below.

An active region used in the experiments was formed by a phonon depopulation fabrication, following procedures similar to what is described in “Terahertz quantum cascade lasers with >1 W output power,” Electron. Lett. 50, 3090311 (2014), by L. Li et al. In particular, the active region was grown via molecular beam epitaxy in a GaAs/Al_{0.15}Ga_{0.85}As material system (wafer number VB0739). Other suitable QC active materials are encompassed by this disclosure, such as other semiconductor materials forming a p-n junction within an active region. The fabrication of metasurfaces followed the procedure for forming metal-metal waveguides. An about 10 μm-thick active QC layer was bonded to a receiving GaAs wafer via copper (Cu)—Cu thermo-compression bonding. Then a SiO₂ layer of about 200 nm in thickness was deposited and patterned in order to isolate a taper, wire-bonding area, and part of the waveguide array area from a top metal contact so that a center circular area of about 1 mm in diameter is electrically biased (see FIG. 1(a) dash circled area). Finally a titanium (Ti)/gold (Au)/nickel (Ni) metallic layer was evaporated and lifted off to provide top metallization and self-aligned etch mask for a subsequent chlorine-based dry etching to define ridges, followed by the removal of Ni layer. Several uniform metasurfaces with a center circular bias area of about 1.5 mm in diameter and a ridge width between about 11 μm to about 12.5 μm were also fabricated for comparison.

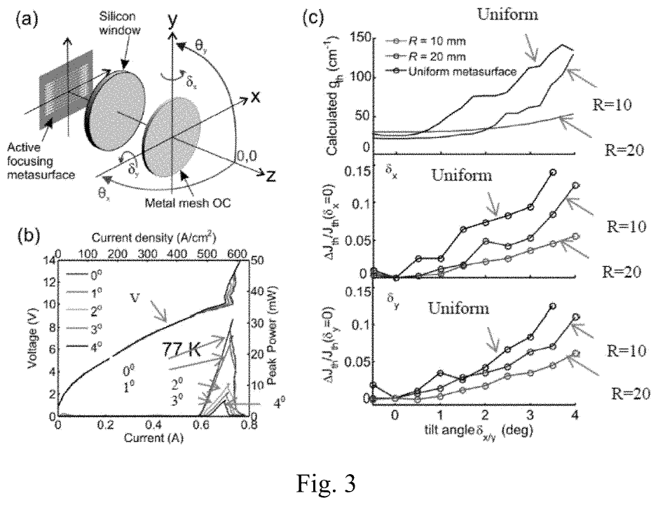

FIG. 3. (a) shows an experimental configuration of a focusing metasurface-based QC-VECSEL, where the metasurface was attached to a Cu submount using indium (In) solder, and mounted inside a cryostat. The cryostat includes an about 3 mm thick silicon window that acts as an intra-cavity etalon filter. A cavity length is about 9 mm—the shortest length allowed by the experimental setup. As the cavity length increases, the VECSEL peak power drops and the threshold current increases, mainly due to the higher air absorption loss and diffraction loss. An output coupler used here is either an inductive metal mesh on an about 100 μm-thick quartz substrate (OC1) or a capacitive metal mesh on an about 75 μm-thick quartz substrate (OC2). The transmittance of the OC1 varied between about 10-24% according to measurements across the frequency range of about 3.2-3.5 THz, due to the substrate's etalon effect. The transmittance of the OC2 varied between about 40-60% according to measurements across the frequency range of about 3.2-3.5 THz, due to the substrate's etalon effect. The tilt angle δ_{x/y} indicates the degree of OC tilting around y/x axis from the perfectly aligned position, as the smaller arrows show.

FIG. 3(b) shows pulsed P-I-V curves at about 77 K for different δ_{y} (with δₓ=0) for R=about 10 mm focusing metasurface (M3.4). FIG. 3(c) shows the measured threshold current density change ratio with respect to Jₜₕ at perfect alignment with δₓ and δ_{y} for QC-VECSELs based upon three different metasurfaces: R=about 10 mm or about 20 mm with about 1 mm diameter circular bias area, and a uniform metasurface with about 1.5 mm diameter circular bias area. The solid lines in the top part are the calculated threshold bulk gain gₜₕ change with the tilt angle δ_{y}.

Testing showed that the focusing metasurface designs were apparently easier to align and more tolerant of misalignment compared to uniform metasurface designs. This was tested by first optimizing the alignment of the cavity to achieve parallelism, and then intentionally introducing angular misalignment in either the x or y axis represented by tilt angles δₓ and δₓ respectively, as shown in FIG. 3(a). A host of pulsed optical power-current-voltage (P-I-V) curves were measured and shown in FIG. 3(b) for increased tilt angles in both axes for QC-VECSELs based upon three metasurfaces: focusing ones of R=about 10 mm or about 20 mm, and a uniform metasurface. The pulsed P-I-V measurements were conducted with about 0.25% overall duty cycle (about 500 ns-long pulses repeated at about 10 kHz, modulated by a slow about 5 Hz pulse train with lock-in detection). To make a fair comparison, for each device the measured change in threshold current density Jₜₕ is plotted normalized to Jₜₕ measured at optimum alignment, as shown in FIG. 3(c). The threshold current increased with the tilt angle in both axes in a modest manner for the two focusing metasurface QC-VECSELs—both devices still lased even with about 4° misalignment. In contrast, the uniform metasurface exhibited a more dramatic rise in Jₜₕ with misalignment, and ceased to lase for misalignments greater than about 3.5°, even though the uniform metasurface has a larger circular biased area of about 1.5 mm diameter and consumes more current.

As such, the focusing effect significantly reduces the cavity's sensitivity to misalignment, in view of the hemispherical Gaussian resonator. The experimental result matches the trend of the simulated results, in which modified Fox-and-Li cavity calculation was used to estimate the threshold bulk gain gₜₕ for each QC-VECSEL to lase at different misaligned angles. The threshold bulk gain was calculated by using a root finder procedure to obtain the value of the metasurface reflectivity for which the computed round-trip cavity loss is zero. The angular misalignment was introduced as a linear shift of the reflection phase of the output coupler. The calculation results revealed a slower trend of threshold bulk gain increase with misalignment for the two focusing metasurfaces than for the uniform one, as shown in the top part of FIG. 3(c). It should be noted that not all loss mechanisms were included in this simulation, but the trend of the threshold current density can be identified.

High power output and slope efficiency were demonstrated for the focusing metasurface QC-VECSELs. All four separate metasurfaces designed for four frequencies in the range of about 3.2-3.5 THz were observed to lase, with the one designed for about 3.4 THz (M3.4) showing the best power performance. At perfect alignment and about 77 K, the R=about 10 mm metasurface QC-VECSEL designed for about 3.4 THz generated a peak power of about 46 mW with the slope efficiency dP/dI=about 413 mW/A when paired with OC2, and about 31 mW peak power with dP/dI=about 227 mW/A with OC1, P-I-V curves of which are plotted in

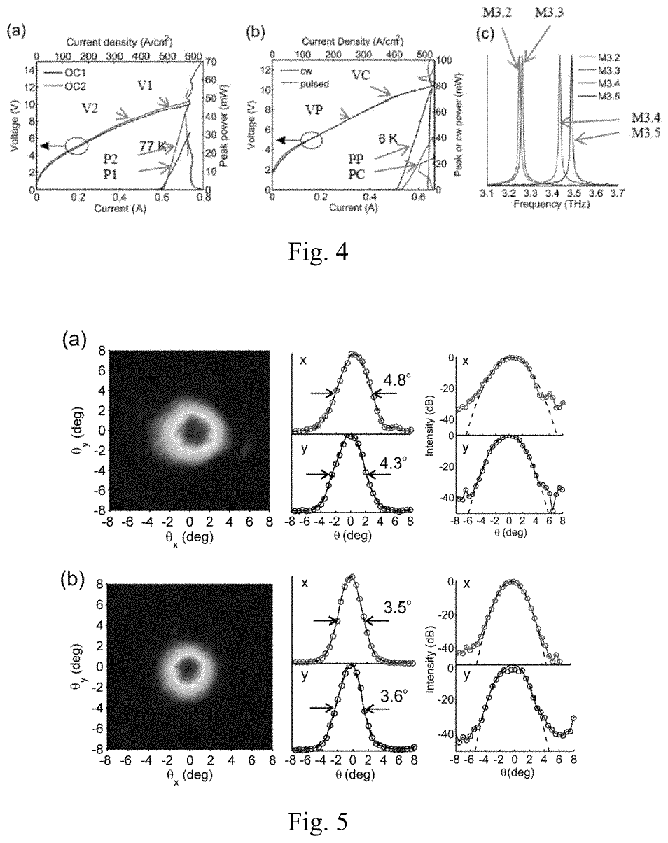

FIG. 4(a). At about 6 K, the pulsed peak power increased to about 78 mW, with dP/dI=about 572 mW/A with OC2 and a peak wall-plug efficiency reaching about 1.15%. Continuous wave (cw) lasing was achieved at about 6 K with a peak power of about 40 mW, dP/dI=about 339 mW/A, and wall-plug efficiency of about 0.6%, as shown in FIG. 4(b). The power was measured using a pyroelectric detector and calibrated using a Thomas-Keating THz absolute power meter with about 100% collection efficiency, given directive beam pattern. For a comparison, the about 77-K P-I-V of a uniform metasurface QC-VECSEL was measured, which showed dP/dI=about 234 mW/A when paired with OC1 (P-I-V curve not shown). The slope efficiency, as well as the output power, dropped when this uniform metasurface was paired with OC2. Even though the focusing metasurface was designed with a smaller circular bias area (about 1 mm diameter) than the uniform metasurface (about 1.5 mm diameter), higher efficiency performance was obtained for the focusing metasurface VECSEL, with the slope efficiency among the best reported numbers so far for a THz QC-laser. The smaller biased area of the focusing design can reduce the total current consumption and benefit cw operation. Further reduction of the biased area may achieve cw performance at higher temperature (e.g., >about 77 K).

FIG. 4(c) shows the lasing spectra for four separate focusing metasurface VECSELs designed for about 3.2-3.5 THz at about 77 K. The spectra are generally close to the designed metasurface frequencies, which are primarily determined by the ridge width at the metasurface center. All lased in single-mode over the entire bias range. This can be attributed to the etalon filter effect of the cryostat window, which caused the cavity loss to vary rapidly with frequency with minima separated by the free spectral range of about 13 GHz. The etalon filter effect, in combination with the finite bandwidth of the metasurface reflective gain and the QC material gain lineshape, strongly favors single-mode operation.

The beam quality of a focusing metasurface was also examined. FIGS. 5(a) and (b) show the far-field beam measured at about 77 K using a 2-axis spherical scanning pyroelectric detector for focusing metasurface QC VECSELs with R=about 10 mm and R=about 20 mm. Beams from both focusing QC-VECSELs exhibited a narrower and more circular near-Gaussian beam profile than the beam pattern for a uniform metasurface. As shown in FIGS. 5(a) and (b), the QC VECSEL with R=about 20 mm focusing metasurface produced a beam with about 3.5°×about 3.6° FWHM angular divergence, and the QC-VECSEL with the R=about 10 mm metasurface produced a beam with about 4.8°×about 4.3° divergence. This matches with the divergence behavior of Gaussian modes in hemispherical resonators—the smaller value of R produces a smaller spot on the output coupler, with consequent faster divergence in the far-field. The beam fits well with a Gaussian intensity profile at least down to about −25 dB, and in some cases down to about −40 dB.

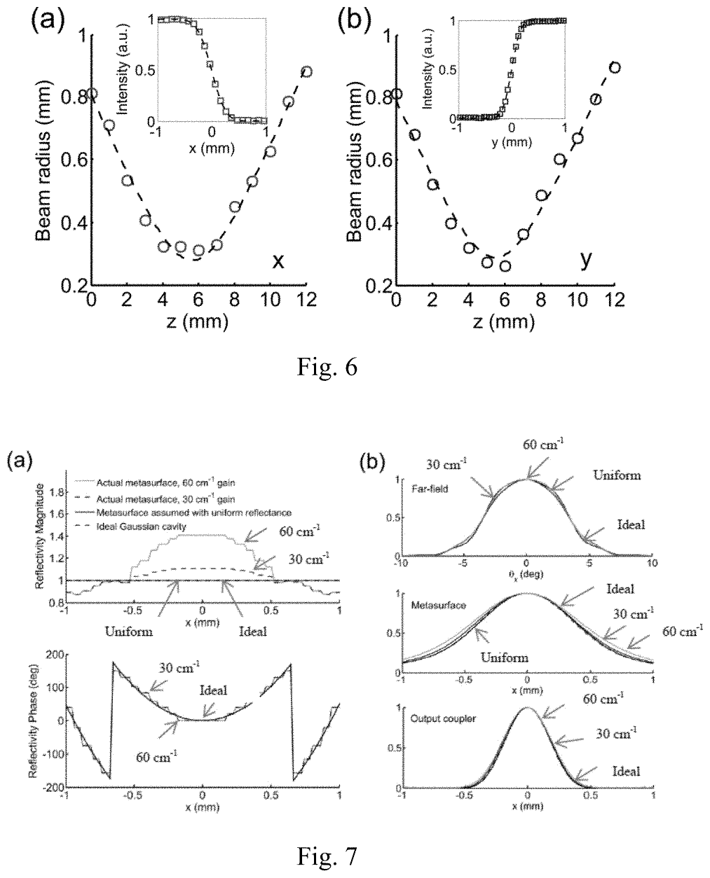

To further assess the beam quality, the beam propagation factor M² was measured using a knife edge procedure through the focus of the beam along the propagation direction. The M² factor is the ratio of the angle of divergence of a laser beam to that of a fundamental Gaussian TEM₀₀ mode with the same beam waist diameter; it has a value of unity (1) for a fundamental Gaussian beam. A value of M²=about 1.3 was measured in both the x and y directions for R=about 20 mm metasurface QC-VECSEL, which is the best reported M² factor for a THz QC-laser based on metal-metal waveguide geometry with no spatial filtering. FIG. 6 shows the beam waist evolution along the optical axis, with parameter fitting results. The peak power associated with this beam was about 27 mW at about 77 K, which led to a high value of brightness Bᵣ=about 1.86×10⁶ Wsr⁻¹m⁻² given by Bᵣ=P/(Mₓ²M_{y}²λ₂), where P is the output power. The M² value for R=about 10 mm metasurface QC-VECSEL with OC2 was measured to be about 2.2 and about 2.5 in x and y directions respectively, with the output power of about 46 mW and Bᵣ=about 1.07×10⁶ Wsr⁻¹m⁻². The slight beam degradation might be due to the stronger diffraction occurring for such a cavity where the cavity length was closer to the focusing curvature radius. Providing electrical bias to the center circular area with diameter of about 1 mm but not to the peripheral area was instrumental in achieving a high beam quality. With the center of the metasurface being selectively pumped, the fundamental Gaussian mode exhibited the highest overlap, and was selectively excited. In addition, even for the R=about 10 mm design, the ridge widths w were relatively uniform within the center biased region, as shown in FIG. 2(b), which reduced the spectral broadening of the gain due to metasurface inhomogeneity. Several focusing devices were tested where the bias area was larger (about 1.5 mm diameter). These VECSELs exhibited beams with large sidelobes, indicating the presence of higher-order Hermite-Gaussian components in the cavity mode.

As explained in this disclosure, amplifying and focusing reflectarray metasurfaces can be a powerful tool to form high-performance THz QC-VECSELs. The inhomogeneous focusing metasurface significantly improves the cavity stability, beam pattern quality, and power efficiency of a QC-VECSEL. The observed slope efficiency was about 572 mW/A. The generated beams demonstrated a near-diffraction limited beam quality (M² as low as about 1.3 or even less) with very narrow divergence and high brightness.

The focusing effect provides a hemisphere cavity with flat optics, which exhibits higher geometric stability than a plano-plano cavity and a directive and circular near-diffraction limited Gaussian beam. The high beam quality leads to greater efficiency, since nearly all of the generated THz power can be directed and focused where desired, allowing omission of inefficient beam-cleanup optics (e.g., apertures and spatial filtering).

The improved stability aspect is particularly valuable for THz QC-lasers, where an active metasurface should be cooled cryogenically. It can be desired to place both the metasurface and an output coupler inside a cryostat for a more compact and convenient setup. However, this presents challenges for optical alignment of the output coupler once the cryostat is closed and cooled down. Since the focusing metasurface has a much greater tolerance of misalignment compared to a plano-plano cavity, it permits implementation of an intra-cryostat cavity.

In addition, non-uniform spatial phase allows the design of focusing devices for compact planar QC-VECSEL cavities. Non-uniform gain (via control of a current injection area) allows the selection of a desired pumping mode, and to retain a total injection current as modest as desired for cw performance. The versatile nature of the reflectarray concept allows the integration of advanced functionality into a planar gain chip, which is highly advantageous in the THz regime, where many optical components are not readily available. Furthermore, the metasurface QC-VECSEL approach implements a modular design, which disentangles the design and optimization of an active metasurface, an output coupling component, and VECSEL cavity characteristics. Thus the design flow can be streamlined and can facilitate improvement or addition of modules.

Simulation and Modeling:

The modeling of the active focusing metasurface was undertaken by performing full-wave finite-element simulations using Comsol Multiphysics 4.4. The iterative Fox-and-Li approach adapted for QC-VECSELs was used to calculate the intra-cavity mode profiles. To evaluate the impact of the non-uniform distribution of reflectance on the metasurface focusing effect, the cavity mode profiles and far-field beam patterns were calculated and compared for four cases: (1) ideal Gaussian cavity with a smooth parabolic phase for R=about 10 mm and uniform unity reflectance, (2) the actual R=about 10 mm focusing metasurface design with phase profile modulated by the ridge width distribution transverse to the ridge array and a “fictitious” uniform reflectance, (3) the actual R=about 10 mm focusing metasurface design with a non-uniform reflectance distribution for about 30 cm⁻¹ within the active material, and (4) the actual R=about 10 mm focusing metasurface design with a non-uniform reflectance distribution for about 60 cm⁻¹ gain within the active material. FIG. 7(a) shows the associated metasurface reflectivity magnitude and phase distributions. The non-uniform reflectance data was obtained by using finite-element simulation to obtain the metasurface reflectance as a function of ridge width. It was assumed that sub-cavities within an about 1 mm center area were biased to produce a bulk gain coefficient of about 30-60 cm⁻¹ within the active material, and the other subcavities outside the area were unbiased so that they were lossy. The range of gain values considered can correspond to operation with different output couplers. For example, a more transmissive output coupler can involve a larger threshold gain to oscillate. Since the metasurface resonance is approximately Lorentzian in lineshape, the modulation of the ridge width to produce the desired phase profile also produces a spatially varying gain profile at a particular frequency, whose variation depends upon the total cavity loss. FIG. 7(b) shows the calculated intensity far-field beam pattern, as well as the modal profiles on the metasurface and the output coupler, for each of the four cases. The results show very similar field distributions. Therefore, the non-uniform reflectance distribution should have a minor effect on the focusing metasurface cavity mode.

High Performance THz Metasurface QC-VECSEL with an Intra-Cryostat Cavity

THz QC lasers are attractive candidates for a number of applications such as local oscillators for heterodyne detection, illumination for active real-time imaging, and tunable laser spectroscopy. For many of these applications, power levels of milliwatts (or sometimes much more) are desired. In pulsed mode operation, THz QC lasers can demonstrate peak power levels of about 10-100 mW, and up to about 2.4 W when cooled to about 10 K. However, due to the challenge of heat removal from an active region, the peak power level typically begins to decline for duty cycles greater than a few percent. If there is capability to cool to near liquid-helium temperatures, the degradation in performance is not too severe—for example, power in cw operation can reach about 230 mW at about 10 K. However, at more practical liquid nitrogen temperatures, heating is more severe: power levels of just about 1-1.5 mW can be obtained in the cw mode at about 77 K, from narrow-ridge metal-metal waveguides, in which the THz mode is tightly confined between metal cladding/contacts placed immediately above and below about 5-10 μm-thick epitaxial active region. This is an advantageous geometry for efficient heat removal since the transverse waveguide dimensions can be made much smaller than the wavelength without cutting off the fundamental mode, which allows low total power dissipation. However, for edge emitters, the facet is a sub-wavelength sized radiating aperture, which leads to a highly divergent beam and low output coupling efficiency due to the strong impedance mismatch between the waveguide and free space. To address this issue, 3^{rd} order distributed feedback (DFB) gratings and graded photonic heterostructures can be implemented in metal-metal waveguides and can show improved beam patterns while preserving the cw power at about 77 K. However, scaling up the output power for these cavity types is still an open question since using wider ridge waveguides tends to degrade the thermal performance, and longer waveguides are more difficult to phase match.

In some embodiments, a QC-VECSEL configuration is demonstrated as a viable architecture for generating multi-milliwatt power above about 77 K combined with a high-quality beam pattern, by implementing a cavity substantially fully contained within a cryostat. In particular, a QC-VECSEL is demonstrated with over about 5 mW power in cw and single-mode operation above about 77 K, in combination with a near-Gaussian beam pattern with a full-width half-maximum divergence as narrow as about 5°×about 5°, with no evidence of thermal lensing. This is realized by creating an intra-cryostat VECSEL cavity to reduce the cavity loss and designing an active focusing metasurface with low power dissipation for efficient heat removal. Also, the intra-cryostat configuration allows the evaluation of QC-VECSEL operation versus temperature, showing a maximum pulsed mode operating temperature of about 129 K. While the threshold current density in the QC-VECSEL is higher compared to certain edge-emitting metal-metal waveguide QC-lasers, the beam quality, slope efficiency, maximum power, and thermal resistance are all significantly improved.

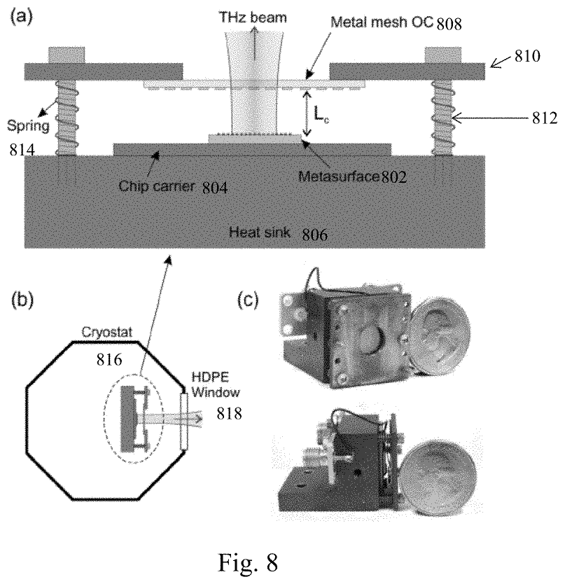

In some QC-VECSELs, an amplifying metasurface reflector is mounted inside a cryostat facing a cryostat window and forms a cavity with an output coupler placed externally. Although convenient for optical alignment, this cavity design sacrifices compactness, and the cryostat window acts as an intra-cavity etalon filter which tends to lock the lasing frequencies. Furthermore, it is estimated that even low loss windows (e.g., high resistivity silicon) exhibit about 2%-3% absorption per pass. In some embodiments, a compact intra-cryostat QC-VECSEL is demonstrated as shown in FIG. 8. A QC metasurface chip 802 is mounted with an indium (In) solder onto a copper chip carrier 804 clamped to a cryostat cold stage 806 serving as a heat sink. An output coupler (OC) 808 is attached onto a metallic frame 810 (e.g., a copper frame), which is held in place substantially parallel to the metasurface chip 802 via multiple (e.g., three) fasteners 812 in the form of screws, each supported by a compression spring 814. The metallic frame 810 defines an opening, and the OC 808 extends across the opening so that an output beam can pass through the opening. The initial alignment takes place with the entire cavity assembly external to a cryostat 816 at about room temperature. The parallelism between the metasurface chip 802 and the OC 808 is achieved by reflecting a visible laser beam from the assembly and then adjusting the fasteners 812 such that diffraction patterns created by a metasurface ridge array and the metal-mesh OC 808 overlap. Following alignment, the assembly is mounted inside the cryostat 816 with an output beam through a high-density polyethylene (HDPE) window 818. While it is possible that thermal contraction during cooling down may introduce angular misalignment of the OC 808 and cause additional diffraction loss, this effect is largely mitigated by using short cavity lengths of about 2-3 mm and was found to be not severe for metasurfaces with sufficient gain.

For a demonstration, an about 2×about 2 mm² active focusing metasurface is used which imposes a parabolic phase profile (focal length of about 10 mm) to the reflected THz wave while amplifying the wave. By selectively depositing a SiO₂ insulation layer underneath a top metal contact, a center circular area of about 0.7-mm diameter is selectively electrically biased to provide gain. This small bias area both acts as a transverse modal filter to select the fundamental Gaussian mode and keeps the total power dissipation sufficiently low to realize cw operation above about 77 K. Another intra-cryostat QC-VECSEL based on a substantially identical focusing metasurface design with a bias area of about 1-mm diameter (about 9 W total power consumption) shows non-steady cw lasing at above about 77 K—the power rolls off until the lasing ceases after several seconds as the cryostat itself is heated. Here, the metasurface with a bias diameter of about 0.7 mm consumes a total power of less than about 5 W. The reduced bias area may lead to degraded transverse mode confinement factor and a resulting higher threshold current density. This effect is deemed not severe given that the estimated modal beam waist 2w₀ on the metasurface is about 0.9 mm, slightly larger than the bias diameter, since the cavity length is kept short between about 2 mm and about 3 mm. To further facilitate cw lasing above 77 K, the lasing threshold is reduced (at the cost of slope efficiency) by pairing the metasurface with a very reflective OC (about 95% reflectance) formed of an inductive metal mesh on an about 0.5 mm thick z-cut crystal quartz substrate.

The fabrication of the active metasurface followed procedures for forming metal-metal waveguides, based upon Cu—Cu thermos-compression wafer bonding and substrate removal. Then, about 200 nm of SiO₂ is deposited and patterned to isolate a taper and wire bonding area from being biased, followed by evaporation and lift-off of Cr/Au/Ni to provide a top metallization and self-aligned etch mask. Metal-metal ridges are then defined by chlorine-based dry etching with subsequent removal of the Ni layer. The QC laser gain medium used is a hybrid bound-to-continuum/resonant-phonon design (wafer number VB0739 with an about 10 μm-thick epitaxial active region grown on an about 625 μm-thick GaAs substrate).

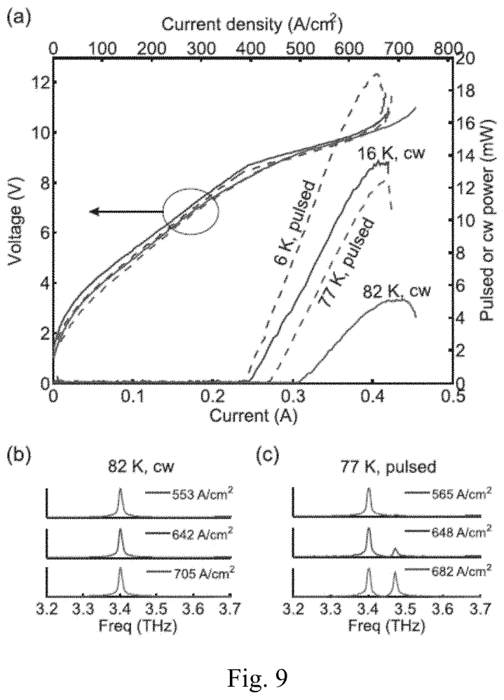

The measured power-current-voltage (P-I-V) curves in cw and pulsed modes are shown in FIG. 9(a). The pulsed measurements were conducted with about 0.25% overall duty cycle (about 500 ns-long pulses repeated at about 10 kHz, modulated by an about 150-Hz pulse train with lock-in detection). The power is measured using a pyroelectric detector and calibrated using a thermopile (Scientech AC2500) with about 100% collection efficiency, given the directive beam pattern, after accounting for the measured about 62% HDPE window transmission. Steady cw operation with an output power of about 5.1 mW is obtained from this intra-cryostat QC-VECSEL at about 82 K, which improves to about 13.5 mW at about 16 K. The cw-mode slope efficiency at about 82 K is about 53 mW/A. In the pulsed mode, the peak power reaches about 12.5 mW at about 77 K and about 19 mW at about 6 K. The pulsed and cw lasing spectra at different biases at about 77 K are shown in FIGS. 9(b) and (c), which do not vary much at liquid-helium temperature. In the cw mode, single-mode lasing at about 3.403 THz is observed to be unchanged over the entire bias range (within the resolution (about 7.5 GHz) of the FTIR spectrometer). In the pulsed mode, lasing in two longitudinal cavity modes separated by about 70 GHz is observed, from which the cavity length of about 2.1 mm is deduced. An initial assessment of device repeatability was made by measuring the P-I-V and spectral characteristics over three cooling cycles. The peak power was measured to be the substantially same over all three measurements; however, a slight red shift of about 2 GHz in lasing frequency and a slight increase in Jₜₕ were observed following the third cooling cycle. This is likely induced by a slight change in the cavity length, which can be alleviated with an improved mechanical design of the cavity setup optimized in thermal reliability.

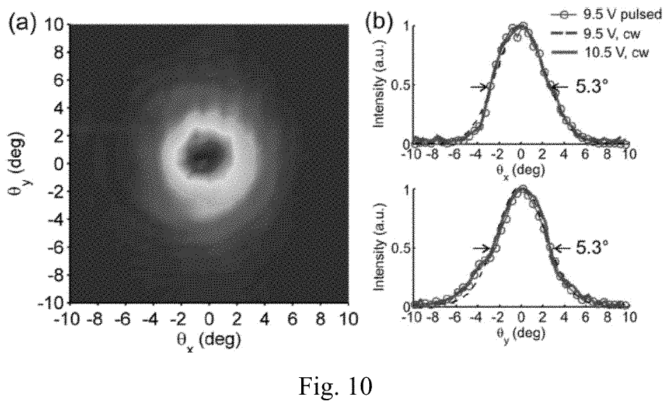

The beam pattern from the intra-cryostat QC-VECSEL is first measured in the pulsed mode, which exhibits a near-Gaussian beam profile with a full-width half-maximum (FWHM) angular divergence of about 5.3°×about 5.3° as shown in FIG. 10(a). The measured divergence is quite close to the calculated far-field divergence of about 4.6° for a hemispherical Gaussian cavity with a concave mirror of about 20-mm curvature radius and about 2.1-mm cavity length. The 1D beam profiles are also measured to be identical in both the cw mode (at two bias points) and pulsed mode (see FIG. 10(b)). This indicates that thermal lensing effects have a negligible impact on THz QC-VECSEL beams. The beam shape is primarily determined by the effective curvature radius of the focusing metasurface, which is primarily built-in by lithographic determination of microcavity dimensions that determine the resonant phase response. Furthermore, the refractive index of GaAs does not change strongly with temperature for low lattice temperatures (fractional changes on the order of 10⁻³ or less), and therefore metasurface microcavity resonances shift very little when heated.

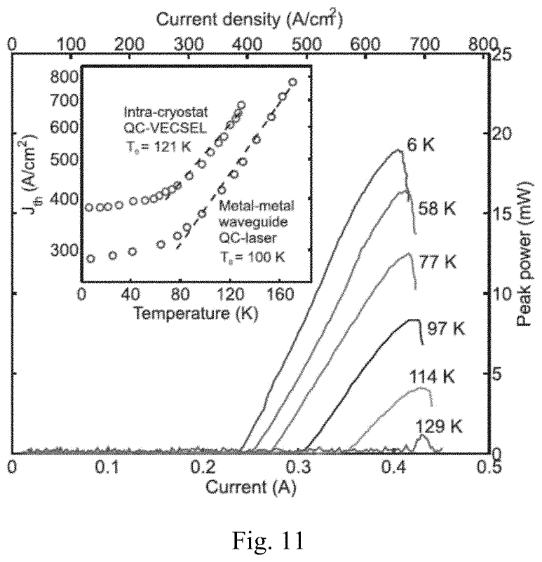

The demonstration of the intra-cryostat VECSEL allows evaluation of its thermal characteristics by measuring a host of P-I curves in the pulsed mode to obtain the threshold current density Jₜₕ versus temperature (see FIG. 11). This is a characterization used for lasers' thermal performance, but has not been performed for QC-VECSELs due to the presence of the cryostat window as an intra-cavity etalon. This is because as the cavity warmed, the thermal expansion within the cryostat would slightly alter the cavity length, which would disrupt the phase matching condition that satisfies the cryostat window's etalon filtering effect, and the laser operation becomes unstable. The intra-cryostat QC-VECSEL exhibits the maximum pulsed operation temperature Tₘₐₓ=about 129 K. The characteristic temperature T₀=about 121 K is extracted by fitting the data above for about 65 K to the exponential function Jₜₕ=J₀e^{T/To}. For comparison, the dependence of Jₜₕ on temperature is also measured for a comparison device: a metal-metal waveguide QC-laser with about 1.47-mm length and about 50-μm width fabricated alongside the metasurface using the same QC gain material. This metal-metal waveguide lases up to a higher temperature with Tₘₐₓ=about 170 K and has a slightly smaller T₀=about 100 K. These data show that there is a threshold and operating temperature penalty incurred by the VECSEL configuration. For example, in the pulsed mode, Jₜₕ=about 285 A/cm² at about 6 K and about 325 A/cm² at about 77 K for the metal-metal waveguide, in comparison to Jₜₕ=about 381 A/cm² at about 6 K and about 433 A/cm² at about 77 K for the intra-cryostat QC-VECSEL. This penalty is a consequence of multiple effects. First, the metal-metal microcavities that comprise the metasurface operate in the TM₀₁ mode at cutoff resonance; due to fringing fields and lower confinement, this mode has a higher loss compared to the fundamental TM₀₀ (guided) mode that the metal-metal waveguide operates. The simulated transparency gain (at which the metasurface gives unity reflectance) is about 17.7 cm⁻¹ in the TM₀₁ mode cutoff frequency of about 3.4 THz, higher than the waveguide loss of about 15.9 cm⁻¹. Second, the QC-VECSEL cavity has additional losses that do not appear for the metal-metal waveguide cavity, including cavity diffraction loss, absorption loss of the metal mesh output coupler, and excess absorption on the metasurface (such as the residual highly doped GaAs on the Cu ground plane). Third, based upon the estimated Gaussian spot size and the about 0.7-mm diameter bias area, the QC-VECSEL has a transverse mode confinement factor of Γₜ of about 0.76, which increases the estimated transparency gain from about 17.7 cm⁻¹ to about 23.3 cm⁻¹ and therefore further increases the threshold gain. In contrast, the confinement factor is nearly unity for a metal-metal waveguide in its fundamental TM₀₀ mode. Fourth, current leakage channels may be present on the metasurface through lateral electrical conductance under the SiO₂ insulation layer at the boundary of the biased and unbiased regions. Finally, the QC-VECSEL has a larger output coupling loss through the coupler—however, this is beneficial and indeed is the reason for the higher slope efficiency and power levels observed for the QC-VECSEL. Even though an excess amount of threshold current density is paid as a cost in the demonstrated intra-cryostat QC-VECSEL, it is justified by the significant improvement of performance compared with the edge-emitting metal-metal waveguide QC-laser. For example, the comparison device produces a single-sided peak pulsed power of about 3.6 mW and a cw power of about 1.6 mW at about 77K. Even more importantly, the beam pattern from the QC-VECSEL is of high quality, whereas much of the power from edge-emitting metal-metal waveguides is not usable since its beams can be highly divergent with significant interference fringes.

There is a further increase in Jₜₕ and reduction in emitted power operating in the cw mode. An effective lattice temperature can be inferred inside the device during cw operation by comparing Jₜₕ in the cw mode to the measured Jₜₕ versus temperature data in the pulsed mode (plotted in FIG. 11) since it is reasonable to assume that temperature measured at the cold stage is very close to the lattice temperature at the very low duty cycle (about 0.25%, with the about 500-ns pulse width) used in the pulsed mode. At the cryogenic condition of liquid nitrogen, the lattice temperature increase ΔT from the pulsed mode to the cw mode is extracted to be about 21 K for the intra-cryostat QC-VECSEL, slightly smaller than about 26 K upon comparison with the metal-metal waveguide QC laser. The thermal resistance Rₜₕ at threshold can be deduced from the relationship Rₜₕ=ΔT/VₜₕJₜₕA, where Vₜₕ is the cw voltage at threshold, Jₜₕ is the cw current at threshold, and A is the device bias area. Calculation gives Rₜₕ=about 7.4K/W, corresponding to a thermal conductance per unit bias area of Gₜₕ=219 W/(K cm²) for the intra-cryostat QC-VECSEL, compared to Rₜₕ=about 10.1 K/W and Gₜₕ=about 135 W/(K cm²) for the metal-metal waveguide QC laser. Given that the two devices have a similar bias area and power consumption (about 2.84 W for QC-VECSEL and about 2.57 W for the metal-metal waveguide at cw lasing threshold and the cryogenic condition of liquid nitrogen), this result indicates better heat dissipation efficiency for the QC-VECSEL. This is attributed to the metasurface being formed of a sparse arrangement of narrow metal-metal ridges and therefore a smaller thermal dissipation density than a single wide metal-metal waveguide with power aggregated together.

As explained in this disclosure, demonstration is made of a high-performance THz QC-VECSEL with a compact intra-cryostat cavity, which exhibits a high cw power of over about 5 mW at above about 77 K in combination with a near-Gaussian beam pattern of about 5.3°×about 5.3° FWHM divergence. Such a device offers a favorable THz laser source for many applications that specify high cw power combined with a high quality beam pattern at moderate cryogenic temperature, such as THz heterodyne detection and real-time imaging. This demonstration indicates the desirability to constrain the total power consumption and reduce the cavity loss in order to sustain the cw operation of QC-VECSELs above about 77 K, which is done here by using a small bias area, a short cavity length, and an intra-cryostat cavity design. The intra-cryostat cavity design also allows quantifying the thermal performance of a THz QC-VECSEL, which reveals the impact in threshold and maximum temperature but with improved thermal dissipation efficiency. Putting aside the underlying QC active material, further improvements in intra-cryostat QC-VECSELs can be attained by (i) reducing any source of loss and channels of current leakage to reduce the threshold current density, (ii) improving heat removal efficiency via better heat sinks (e.g., substrate thinning), (iii) further reducing the bias area to reduce the total drive current, (iv) further reducing the power dissipation density on the metasurface by designing sparse patch antenna reflectarrays, and (v) optimizing the mechanical design of the cavity setup to improve the device reliability with multiple cooling cycles. Furthermore, dynamic frequency tuning and stabilization are contemplated with the intra-cryostat cavity setup by incorporating piezoelectric actuators to control the cavity length, which facilitates its application as a source for spectroscopy.

### QC Lasers for Broadband Operation

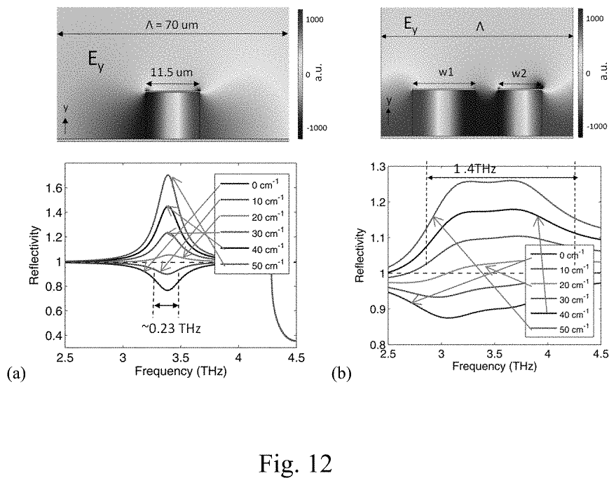

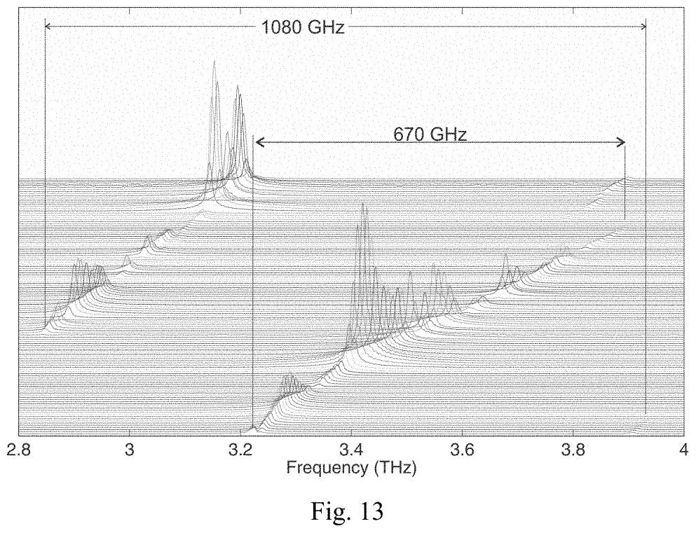

In order to render an active amplifying metasurface suitable for broadband operation, a strategy according to some embodiments is to leverage an inhomogeneous design, where a metasurface unit cell, which is repeated across the metasurface, includes more than a single subcavity as a microcavity resonator or antenna. For example, optical coupling between multiple heterogeneous subcavities can be used to increase a bandwidth of a response and reduce a dispersion. For example, a homogeneous metasurface formed of a repeating subcavity with a single consistent width and resonant at about 3.4 THz can have a FWHM of the gain of about 200 GHz. However, it can be demonstrated that using two dissimilar subcavities per unit cell in a coupled-resonator approach can increase the gain bandwidth to over about 1400 GHz (see FIG. 12). By placing this metasurface in a tunable laser cavity, this coupled-resonator metasurface is shown to lase at frequencies separated by about 1.08 THz, evidence of the broadband enhancement provided by the coupled-resonator metasurface (see FIG. 13). The broadband coupled-resonator metasurface can also reduce a group delay dispersion (GDD), which may be desired for frequency comb or mode-locked lasers. Simulations show that the GDD can be reduced from about 5-10 ps² in a single resonator metasurface to about 0.2 ps² in the coupled-resonator metasurface.

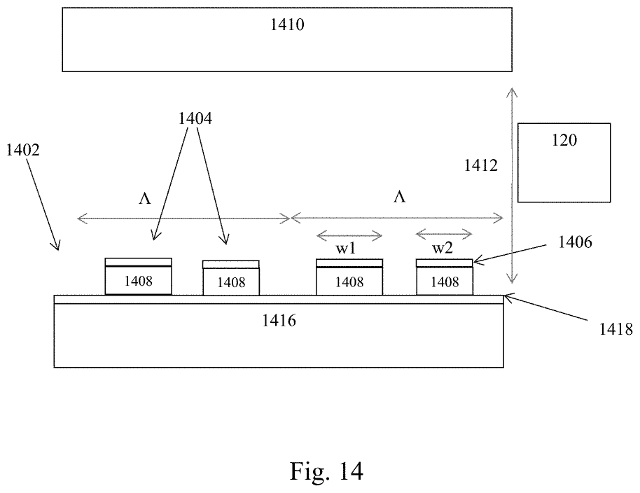

FIG. 14 is a schematic diagram of some embodiments of a broadband QC-VECSEL formed of an active metasurface 1402 in conjunction with an output coupler 1410. The metasurface 1402 and the output coupler 1410 collectively form a cavity 1412 having a cavity length. The metasurface 1402 includes a substrate 1416 and an array of subcavities 1404 disposed thereon in the form of inhomogeneous metal-metal waveguide ridges. In particular, the array of subcavities 1404 includes a repeating unit cell of a group of multiple (here, two) subcavities 1404 having different widths w1 and w2, and the unit cell is repeated across the metasurface 1402 with a period Λ. In some embodiments, one subcavity 1404 per unit cell has a substantially consistent width w1 along its lengthwise direction at least within a center biased region of the metasurface 1402, and another subcavity 1404 per unit cell has a substantially consistent width w2 along its lengthwise direction at least within the center biased region of the metasurface 1402. In some embodiments, w1 is greater than w2, such as at least about 1.05 times greater, at least about 1.1 times greater, at least about 1.2 times greater, at least about 1.3 times greater, at least about 1.4 times greater, or at least about 1.5 times greater. Each subcavity 1404 includes a strip of a QC active material 1408 sandwiched between a strip of a top metallic layer 1406 and a bottom metallic layer 1418. In the illustrated embodiments, the bottom metallic layers 1418 are interconnected and integrally formed as a common metallic ground plane. As shown in FIG. 14, an actuator 120, such as a piezoelectric actuator, is connected between the metasurface 1402 and the output coupler 1410 to adjust a spacing therebetween to control the cavity length. Although two inhomogeneous subcavities 1404 per unit cell are shown in FIG. 14, any multiple number of inhomogeneous subcavities 1404 can be included per unit cell, such as two or more, three or more, four or more, and so forth. Also, it is contemplated that widths of the subcavities 1404 also can vary along their lengthwise directions, such as by spatially modulating the widths according to a distance from a metasurface center to attain a focusing effect in conjunction with broadband operation. Certain aspects of the QC-VECSEL shown in FIG. 14 can be similarly implemented as explained with reference to FIG. 1 and FIG. 8, and those aspects are not repeated.

While coupled-resonator metasurfaces based upon side-by-side coupled subcavities are explained, coupled-resonator metasurfaces having stacked implementations are also contemplated, where coupled and adjacent subcavities are on top of one another, providing a further degree of freedom and opportunity for bandwidth enhancement.

As used herein, the singular terms “a,” “an,” and “the” may include plural referents unless the context clearly dictates otherwise. Thus, for example, reference to an object may include multiple objects unless the context clearly dictates otherwise.

As used herein, the term “set” refers to a collection of one or more objects. Thus, for example, a set of objects can include a single object or multiple objects.

As used herein, the terms “connect,” “connected,” and “connection” refer to an operational coupling or linking. Connected objects can be directly coupled to one another or can be indirectly coupled to one another, such as via one or more other objects.

As used herein, the terms “substantially” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be “substantially” or “about” the same as a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a characteristic or quantity can be deemed to be “substantially” consistent or uniform if a maximum numerical value of the characteristic or quantity is within a range of variation of less than or equal to 10% of a minimum numerical value of the characteristic or quantity, such as less than or equal to 5%, less than or equal to 4%, less than or equal to 3%, less than or equal to 2%, less than or equal to 1%, less than or equal to 0.5%, less than or equal to 0.1%, or less than or equal to 0.05%.

In the description of some embodiments, an object provided “on,” “over,” “on top of,” or “below” another object can encompass cases where the former object is directly adjoining (e.g., in physical contact with) the latter object, as well as cases where one or more intervening objects are located between the former object and the latter object.

Additionally, concentrations, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a range of about 1 to about 200 should be understood to include the explicitly recited limits of about 1 and about 200, but also to include individual values such as about 2, about 3, and about 4, and sub-ranges such as about 10 to about 50, about 20 to about 100, and so forth.

While the disclosure has been described with reference to the specific embodiments thereof, it should be understood by those skilled in the art that various changes may be made and equivalents may be substituted without departing from the true spirit and scope of the disclosure as defined by the appended claims. In addition, many modifications may be made to adapt a particular situation, material, composition of matter, method, operation or operations, to the objective, spirit and scope of the disclosure. All such modifications are intended to be within the scope of the claims appended hereto. In particular, while certain methods may have been described with reference to particular operations performed in a particular order, it will be understood that these operations may be combined, sub-divided, or re-ordered to form an equivalent method without departing from the teachings of the disclosure. Accordingly, unless specifically indicated herein, the order and grouping of the operations are not a limitation of the disclosure.

1. A metasurface for quantum-cascade lasing, comprising:
a substrate; and
an array of subcavities disposed on the substrate, wherein each subcavity in the array of subcavities includes:
a first metallic layer disposed on the substrate;
a layer of a quantum-cascade laser active material disposed on the first metallic layer; and
a second metallic layer disposed on the layer of the quantum-cascade laser active material,
wherein at least some subcavities in the array of subcavities have inhomogeneous widths, and the array of subcavities is configured to reflect an incident light of at least one resonant frequency with amplification.

2. The metasurface of claim 1, wherein widths of subcavities at respective positions in the array of subcavities vary according to distances from a reference point of the metasurface to the respective positions.

3. The metasurface of claim 1, wherein a width of at least one subcavity varies along its lengthwise direction.

4. The metasurface of claim 1, wherein a width of at least one subcavity at respective positions along its lengthwise direction varies according to distances from a reference point of the metasurface to the respective positions.

5. The metasurface of claim 1, wherein widths of subcavities in the array of subcavities are spatially modulated so that a reflected light from the metasurface has a phase shift that varies according to a distance from a reference point of the metasurface.

6. The metasurface of claim 1, wherein widths of subcavities in the array of subcavities are spatially modulated so that a reflected light from the metasurface has a phase shift that increases according to a distance from a reference point of the metasurface.

7. The metasurface of claim 1, wherein the array of subcavities includes a repeating unit cell of a group of multiple subcavities having different widths.

8. The metasurface of claim 1, wherein the array of subcavities is configured to reflect and focus the incident light of the resonant frequency with amplification.

9. A metasurface for quantum-cascade lasing, comprising:
a substrate;
a first metallic layer disposed on the substrate;
an array of quantum-cascade laser active strips disposed on the first metallic layer such that a portion of the first metallic layer is covered by the array of quantum-cascade laser active strips and another portion of the first metallic layer is exposed from the array of quantum-cascade laser active strips; and
an array of metallic strips disposed on the array of quantum-cascade laser active strips,
wherein at least some strips in the array of quantum-cascade laser active strips have inhomogeneous widths, and the metasurface is configured to reflect an incident light of at least one resonant frequency with amplification.

10. The metasurface of claim 9, wherein widths of strips in the array of quantum-cascade laser active strips are spatially modulated so that a reflected light from the metasurface has a phase shift that varies according to a distance from a reference point of the metasurface.

11. The metasurface of claim 9, wherein widths of strips in the array of quantum-cascade laser active strips are spatially modulated so that a reflected light from the metasurface has a phase shift that increases according to a distance from a reference point of the metasurface.

12. The metasurface of claim 9, wherein the array of quantum-cascade laser active strips includes a repeating unit cell of a group of multiple strips having different widths.

13. A quantum-cascade laser comprising:
the metasurface of claim 1 or claim 9; and
an output coupler connected to the metasurface to form a cavity with the metasurface to generate a quantum-cascade laser beam.

14. The quantum-cascade laser of claim 13, wherein the output coupler is a flat reflector.

15. The quantum-cascade laser of claim 13, further comprising:
a heat sink connected to the metasurface; and
a cryostat that houses the heat sink and the metasurface.

16. The quantum-cascade laser of claim 15, wherein the cryostat includes a window to transmit the quantum-cascade laser beam.

17. The quantum-cascade laser of claim 15, wherein the output coupler is housed within the cryostat.

18. The quantum-cascade laser of claim 13, further comprising an actuator connected between the metasurface and the output coupler to adjust a spacing therebetween.
